(19) United States
(12) Patent Application Publication
(10) Pub. No.: US 2007/0165391 A1
(43) Pub. Date: Jul. 19, 2007

(54) Universal DIY kit for LCD keyboard mouse console and KVM switch integration

(75) Inventors: Sharon Lin Charna, Newport Coast, CA (US); Jim Gau, Carlsbad, CA (US)

Correspondence Address: BIRCH STEWART KOLASCH & BIRCH, PO BOX 747, FALLS CHURCH, VA, 22040-0747, US

(73) Assignee: At Box Technology Inc., Irvine, CA (US)

(21) Appl. No.: 11/604,233

(22) Filed: Nov. 27, 2006

Related U.S. Application Data
(60) Provisional application No. 60/739,787, filed on Nov. 28, 2005.

(51) Int. Cl. H05K 7/04

(52) U.S. Cl. 361/807

(57) ABSTRACT

A universal DIY kit for integrating a LCD keyboard mouse console, a rackmount KVM switch, and the consoles of a rack system is proposed. The universal DIY kit includes attachment brackets. The rackmount LCD keyboard mouse console is integrated with a generic rackmount KVM switch by attaching the universal DIY kit onto the rack system, screwing the universal DIY kit onto the generic rackmount KVM switch, and screwing onto rack system, in which one side of the attachment bracket is designed to allow the user to screw the attachment bracket onto the legs of the LCD keyboard mouse console, and the other side of the universal DIY kit is to hold the rackmount KVM switch. As a result, the cables between the LCD keyboard mouse console system and the rackmount KVM switch are become more organized.

### CROSS-REFERENCE TO RELATED APPLICATIONS

This application claims the benefit of U.S. Provisional Application No. 60/739,787, filed Nov. 28, 2005.

### FIELD OF THE INVENTION

The present invention is related to a universal DIY kit for rackmount console and rackmount KVM switch integration. In particular, it simplifies the installation of rackmount KVM switches onto rackmount LCD keyboard mouse console.

### BACKGROUND OF THE INVENTION

A rackmount LCD keyboard mouse console system usually comes with a built-in LCD panel, a keyboard, and a computer mouse. Users today uses all of the possible available spaces in a rack; and the rackmount LCD keyboard mouse console system virtually eliminates the required space that was necessary with the traditional monitors. In general, a rackmount LCD keyboard mouse console system and a rackmount KVM switch are two independent systems. Users have to connect the rackmount LCD keyboard mouse console system and the KVM switches using a plurality of cables. Additionally, in most cases, the rackmount LCD keyboard mouse console system and the KVM switch usually occupy two separate spaces inside a rack cabinet. In order to save the rack cabinet space, some rackmount LCD keyboard mouse console systems also integrate a build-in KVM switch. In this case, users have to pay more for, and it is not KVM model independent.

As shown in FIG. 1, a traditional rackmount LCD keyboard mouse console with build-in computer keyboard, computer mouse, and computer video display modules are to be working with the rack system.

As shown in FIG. 2, a design illustrating a conventional rackmount LCD keyboard mouse console 20 with a build-in KVM switch 10 is shown to be working with a rack system 5, and to be inside of the rack system 5. The built-in KVM switch 10 is shown to be part of the rackmount LCD keyboard mouse console 20. In addition, the rackmount LCD keyboard mouse console 20 includes a computer keyboard 25, a computer mouse 28, and a computer video display 30. One or more of keyboard signals 40, video signals 45, and mouse signals 50 are transmitted by the build-in KVM switch 10 inside the rackmount LCD keyboard mouse console 20.

### SUMMARY OF THE INVENTION

An objective of the present invention is to present a universal DIY kit to integrate a rackmount LCD keyboard mouse console together with a rackmount KVM switch.

The proposed universal DIY kit is universal to any standard KVM switch; that is, it is to be manufacturer and model independent. It allows the users to do-it-yourself (DIY) when it comes to integrating a rackmount KVM switch into the rear of a rackmount LCD keyboard mouse console system. Since the rackmount KVM switch is in the rear of the rackmount LCD keyboard mouse console system, this method does not occupy additional space inside the rack cabinet.

For more detailed information regarding advantages or features of the present invention, examples of embodiments will be described below with reference to the annexed drawings.

### BRIEF DESCRIPTION OF THE DRAWINGS

The present invention will be apparent to those skilled in the art by reading the following detailed description of a plurality of embodiments thereof, with reference to the attached drawings, in which:

FIG. 1 is a traditional rackmount LCD keyboard mouse console working with the rack system;

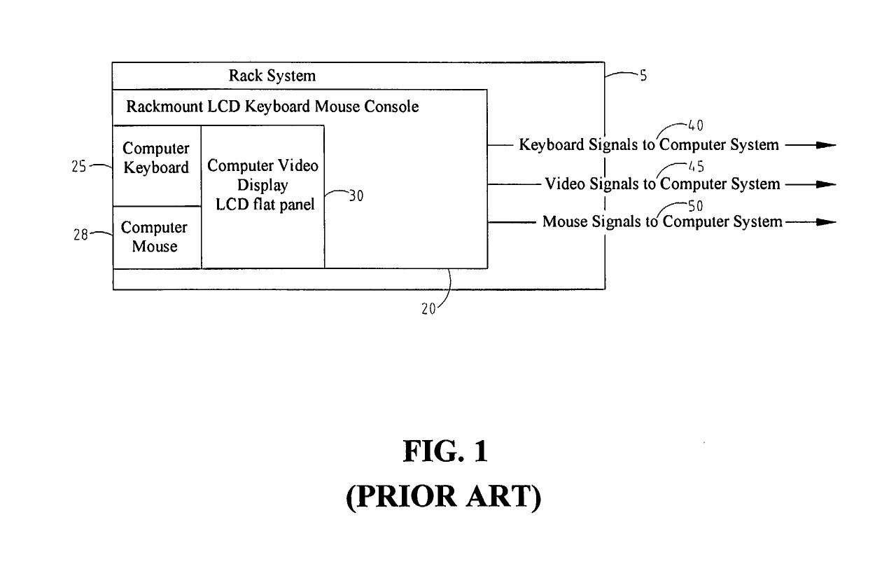

FIG. 2 is a block diagram of a design of a conventional rackmount LCD keyboard mouse console with a built-in KVM switch working with the rack system;

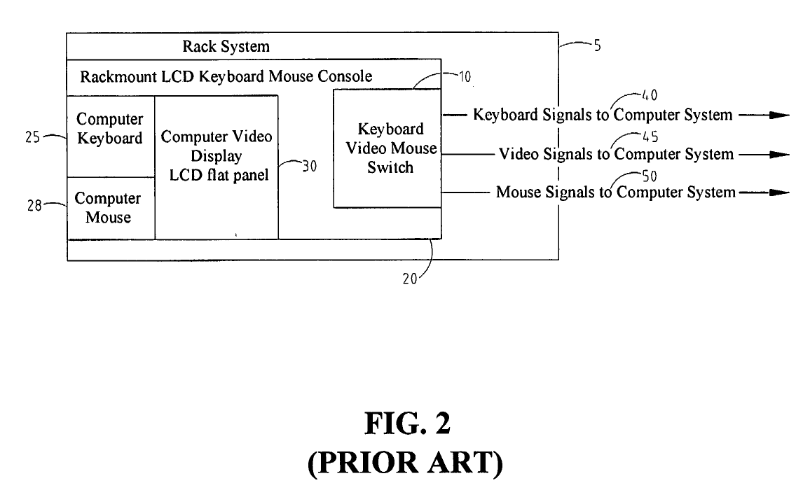

FIG. 3 is a block diagram of the rackmount LCD keyboard mouse console configured with a generic rackmount KVM switch by using a universal DIY kit, according to the first embodiment of the present invention;

FIG. 4 is a perspective view of a universal DIY kit for the configuring of the LCD Keyboard Mouse Console with a generic rackmount KVM switch, according to a second embodiment of the present invention; and

FIG. 5 is a perspective view of an attachment bracket of the universal DIY kit for the integration of the LCD Keyboard Mouse Console and the rackmount KVM switch, according to the second embodiment of the present invention.

### DETAILED DESCRIPTION OF THE EMBODIMENTS

A rackmount LCD keyboard mouse console as referred to in the present invention is understood to be equivalent to a LCD keyboard mouse console, and all of the equivalent variants that are commonly known in the art.

A KVM switch, a generic KVM switch, a standard KVM switch, a rackmount KVM switch, a generic rackmount KVM switch, and a rack mount KVM switch as referred to in the present invention and used interchangeably throughout the present invention are all similar variants of KVM switches which are commonly known in the art.

A computer mouse as referred to in the present invention is also understood to be equivalent to all of the many other equivalent variants of computer mouse as that are commonly known in the art.

A computer video display can be in the form of a LCD flat panel display or any other equivalent variants of video displays that are commonly known in the art.

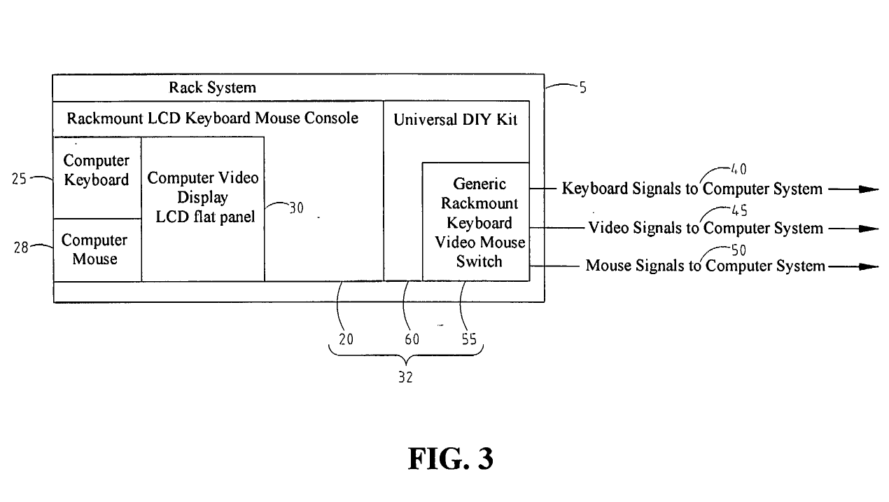

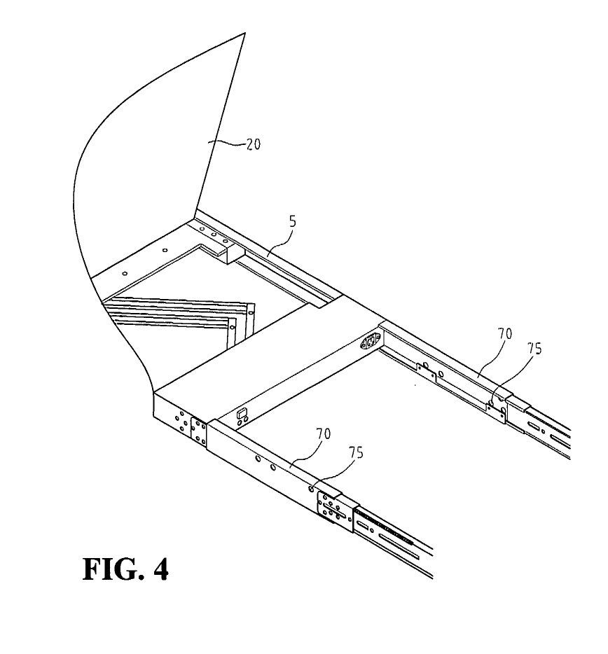

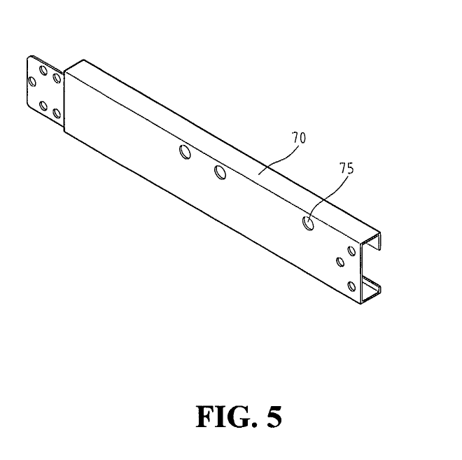

As shown in FIG. 3, the rackmount LCD keyboard mouse console 20 is to be integrated with a generic rackmount KVM switch 55, according to the first embodiment. A user can perform do-it-yourself (DIY) by screwing a universal DIY kit 60 onto the rackmount LCD keyboard mouse console 20 and screwing onto the generic rackmount KVM switch 55. An integrated system 32 is then screwed onto the consoles of the rack system 5. One side of the universal DIY kit 60 is designed to allow the user to screw the universal DIY kit 60 onto the legs of the LCD keyboard mouse console 20. The other side of the universal DIY kit 60 can hold the generic rackmount KVM switch 55. The universal DIY kit 60, as referred to in the present invention, can be a kit universal to any generic rackmount KVM switch 55 having one or more of the following types of cables: PS/2 keyboard cable, PS/2 mouse cable, VGA cable, USB cable, and power cable. The universal DIY kit 60 is to include a plurality of attachment brackets 70, as is shown in FIG. 4. As illustrated in FIG. 5, the attachment bracket 70 has a plurality of specifically positioned screw holes 75 to allow for the screwing or attaching of the generic rackmount KVM switch 55, the rackmount LCD keyboard mouse console 20, and the consoles of the rack system 5. By using the universal DIY kit 60, the generic rackmount KVM switch 55 is integrated to the rear of the LCD keyboard mouse console 20. The universal DIY kit may also come with a plurality of cables for the connection between the LCD keyboard mouse console system 20 and the generic rackmount KVM switch 55. The cables between the LCD keyboard mouse console system 20 and the generic rackmount KVM switch 55 become more organized by simply connecting the cables to the corresponding ports of the systems.

As shown in FIG. 4, a universal DIY kit 60 according to the second embodiment of the present invention is to provide for the integration of a rackmount LCD keyboard mouse console 20 with a generic rackmount KVM switch 55.

As shown in FIG. 5, the attachment bracket 70 of the universal DIY kit 60 for the integration of the LCD keyboard mouse console 20 and the rackmount KVM switch 55 is shown to possess a plurality of specifically positioned screw holes 75, according to the second embodiment of the present invention. In addition, each of the attachment brackets 70 is shown to be bent partially around the side rail of a console of the rack system. It is evident that the physical dimensions of the attachment bracket 70 and the universal DIY kit 60 as a whole can be estimated based upon a visual interpretation using FIGS. 4 and 5, and as well as upon common knowledge available in the related art. Referring to FIGS. 4 and 5, when viewed together, the universal DIY kit 60 according to the second embodiment of the present invention has each of the attachment brackets 70 to include eleven screw holes 75 that are distributed at a plurality of specified locations.

Although the present invention has been described with reference to the embodiments thereof, it is apparent to those skilled in the art that a variety of modifications and changes may be made without departing from the scope of the present invention which is intended to be defined by the appended claims.

What is claimed is:

1. A universal DIY kit for integrating a LCD keyboard mouse console, a rackmount KVM switch, and the consoles of a rack system, comprising:
a plurality of attachment brackets with a plurality of specifically positioned screw holes, wherein the rackmount LCD keyboard mouse console is integrated with a generic rackmount KVM switch by screwing the universal DIY kit onto the rackmount LCD keyboard mouse console and screwing onto the generic rackmount KVM switch, and screwing the integrated system onto the rack system, wherein one side of the attachment bracket is designed to allow the user to screw the attachment bracket onto the legs of the rackmount LCD keyboard mouse console, and the other side of the universal DIY kit is to hold the rackmount KVM switch, and the attachment bracket uses the specifically positioned screw holes to allow for the attachment of the generic rackmount KVM switch and the rackmount LCD keyboard mouse console onto the consoles of the rack system, and the generic rackmount KVM switch is thereby integrated to the rear of the rackmount LCD keyboard mouse console.

2. The universal DIY kit as claimed in claim 1, further comprising two attachment brackets, each of a specified dimension.

3. The universal DIY kit as claimed in claim 1, wherein each of the attachment brackets has eleven screw holes distributed at specified locations.

4. The universal DIY kit as claimed in claim 1, wherein each of the attachment brackets is bent partially around the side rail of the rack system.

5. A method for the integration of a LCD keyboard mouse console, a generic rackmount KVM switch, and the consoles of a rack system, comprising the steps of:
fabricating a universal DIY kit;
integrating a rackmount LCD keyboard mouse console with a generic rackmount KVM switch by screwing the universal DIY kit onto the consoles of the rack system, and screwing the universal DIY kit onto the generic rackmount KVM switch, and onto the consoles of the rack system;
screwing the attachment bracket of the universal DIY kit onto the legs of the rackmount LCD keyboard mouse console;
holding the rackmount KVM switch using the attachment bracket of the universal DIY kit; and
integrating the generic rackmount KVM switch to the rear of the rackmount LCD keyboard mouse console.
